(19) United States
(12) Patent Application Publication
(10) Pub. No.: US 2008/0003767 A1
(43) Pub. Date: Jan. 3, 2008

(54) Method for fabricating semiconductor device

(76) Inventors: Ik-Soo Choi, Kyoungki-do (KR); Dae-Young Seo, Kyoungki-do (KR)

Correspondence Address: BLAKELY SOKOLOFF TAYLOR & ZAFMAN, 1279 OAKMEAD PARKWAY, SUNNYVALE, CA, 94085-4040, US

(21) Appl. No.: 11/647,813

(22) Filed: Dec. 29, 2006

(30) Foreign Application Priority Data
Jun. 29, 2006 (KR) 2006-0059254
Dec. 8, 2006 (KR) 2006-0124738

(51) Int. Cl. H01L 21/02

(52) U.S. Cl. 438/396; 257/E21.011

(57) ABSTRACT

A method for fabricating a semiconductor device includes forming a fuse line over a first region of a substrate, forming a first insulation layer over the fuse line and the substrate, forming a capacitor including an electrode over a second region of the substrate, such that a conductive layer for the electrode is patterned over the first insulation layer of the first region to overlap with the fuse line, forming a second insulation layer over the capacitor, etching the second insulation layer using the patterned conductive layer of the first region as an etch stop layer, and etching the patterned conductive layer and the first insulation layer to make a portion of the first insulation layer remain over the fuse line at a certain thickness.

### CROSS-REFERENCES TO RELATED APPLICATIONS

The present invention claims priority of Korean patent application numbers 10-2006-0059254 and 10-2006-0124738, filed on Jun. 29, 2006, and Dec. 8, 2006, respectively, which are incorporated by reference in their entirety.

### BACKGROUND OF THE INVENTION

The present invention relates to a method for fabricating a semiconductor device; and more particularly, to a method for fabricating a fuse box of a semiconductor device.

A fuse box is formed to repair a defect which may be generated in a semiconductor device. The fuse box has a structure in which a thin insulation layer is formed over a fuse line.

FIGS. 1A to 1C illustrate a typical method for fabricating a semiconductor device. As shown in FIG. 1A, a first insulation layer 12 including a plurality of bit line contact plugs 13, and a plurality of bit lines 14 are sequentially formed over an upper portion of a substrate 11. A conductive layer forming the bit lines 14 of the cell region is patterned in the peripheral region to form a fuse line 14A.

A second insulation layer 15 is formed over the above resultant structure. A plurality of storage node contact plugs 16 penetrating the second insulation layer 15 are formed. A plurality of capacitors connected to the storage node contact plugs 16 are formed in the cell region. Each of the capacitors includes a bottom electrode 17, a dielectric layer 18, and a top electrode 19. A third insulation layer 20 is formed over the top electrode 19.

As shown in FIG. 1B, a metal contact plug 21 penetrating the third insulation layer 20 of the cell region, a first metal line connected to the metal contact plug 21, a fourth insulation layer 23, a second metal line 24, and a passivation layer 25 are sequentially formed. A mask pattern 26 exposing a fuse box region is formed thereon.

As shown in FIG. 1C, the passivation layer 25, the fourth insulation layer 23, the third insulation layer 20, and the second insulation layer 15 are sequentially etched to make the second insulation layer 15 remain in the peripheral region at a certain thickness. A patterned passivation layer 25A, a patterned fourth insulation layer 23A, a patterned third insulation layer 20A, and a patterned second insulation layer 15A are obtained in the peripheral region.

As described above, the second insulation layer 15, the third insulation layer 20, the fourth insulation layer 23, and the passivation layer 25 are etched once to form a fuse box. However, it may be difficult to make the insulation layer remain over the fuse line 14A to a uniform thickness ranging from about 2,000 Å to about 3,000 Å while performing a repair etching process. Due to a poor etch uniformity of an etching apparatus and a thick layer to be etched, a uniform insulation layer cannot remain in a wafer. Accordingly, a role of a repair fuse box may not be properly served and thus, yields of devices may be decreased.

### SUMMARY OF THE INVENTION

Embodiments of the present invention are directed to provide a method for fabricating a semiconductor device, wherein the method makes an insulation layer remain at a uniform thin thickness over a fuse line and thus, an improved repair fuse box can be obtained.

In accordance with an aspect of the present invention, there is provided a method for fabricating a semiconductor device. The method includes forming a fuse line over a first region of a substrate, forming a first insulation layer over the fuse line and the substrate, forming a capacitor including an electrode over a second region of the substrate, such that a conductive layer for the electrode is patterned over the first insulation layer of the first region to overlap with the fuse line, forming a second insulation layer over the capacitor, etching the second insulation layer using the patterned conductive layer of the first region as an etch stop layer, and etching the patterned conductive layer and the first insulation layer to make a portion of the first insulation layer remain over the fuse line at a certain thickness.

In accordance with another aspect of the present invention, there is provided a method for fabricating a semiconductor device including a cell region and a peripheral region. The method includes forming a first conductive layer over a substrate, patterning the first conductive layer to form a bit line in the cell region and a fuse line in the peripheral region, forming a first insulation layer over the resultant structure obtained by forming the bit line in the cell region and the fuse line in the peripheral region, forming a capacitor including a bottom electrode, a dielectric layer, and a top electrode in the cell region, such that a conductive layer for the top electrode is patterned over the first insulation layer of the peripheral region to be overlapped with the fuse line, forming a second insulation layer over the capacitor, etching the second insulation layer using the patterned conductive layer of the peripheral region as an etch stop layer, and etching the patterned conductive layer and the first insulation layer to make a portion of the first insulation layer remain over the fuse line at a certain thickness.

### BRIEF DESCRIPTION OF THE DRAWINGS

FIGS. 1A to 1C illustrate a typical method for fabricating a semiconductor device; and

FIGS. 2A to 2E illustrate a method for fabricating a semiconductor device in accordance with an embodiment of the present invention.

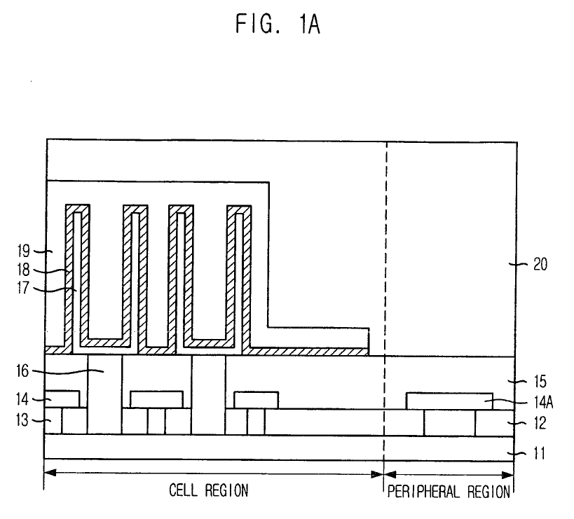

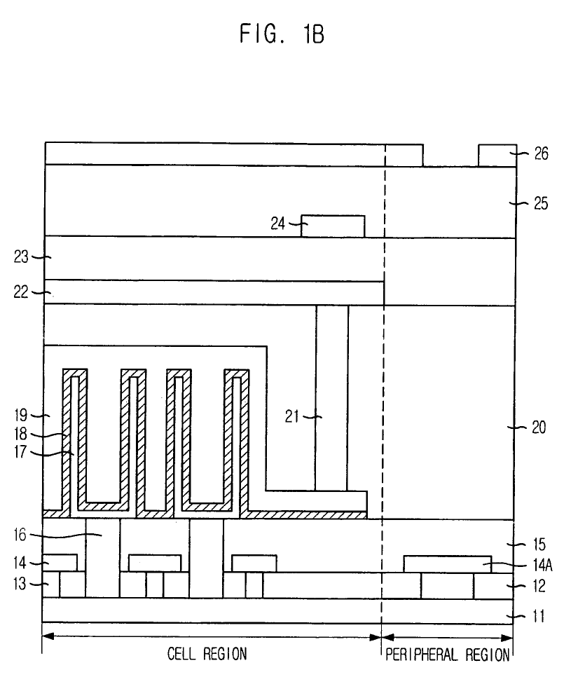

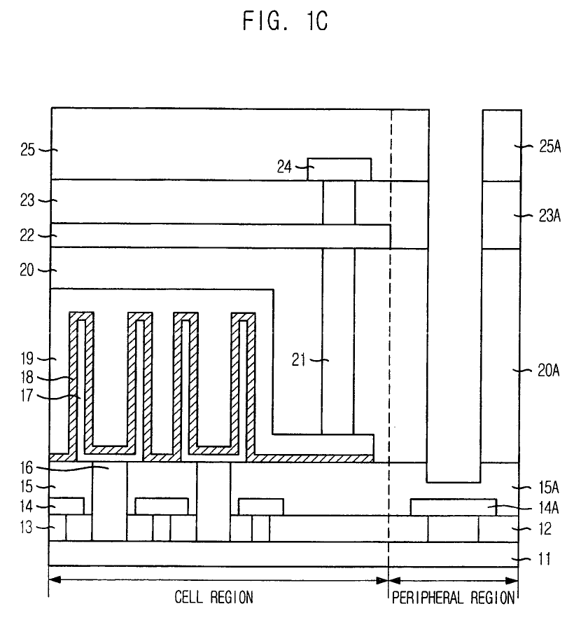

### DESCRIPTION OF SPECIFIC EMBODIMENTS

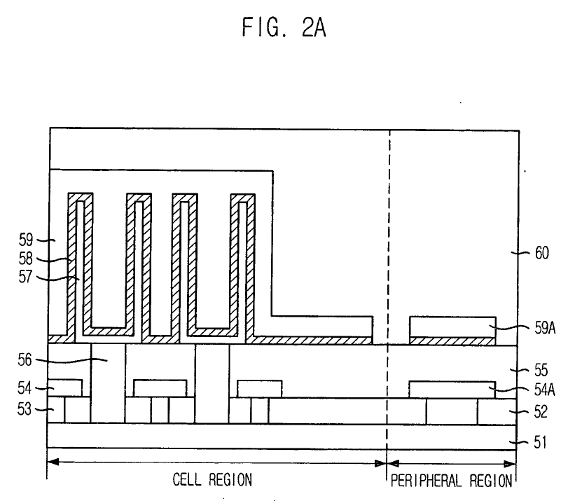

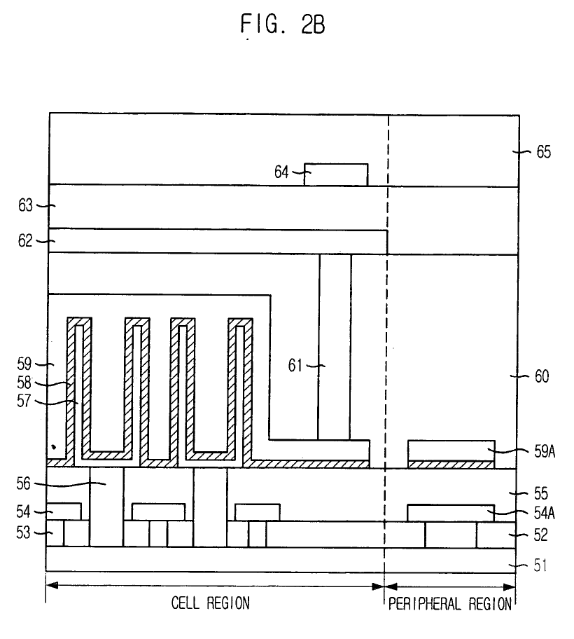

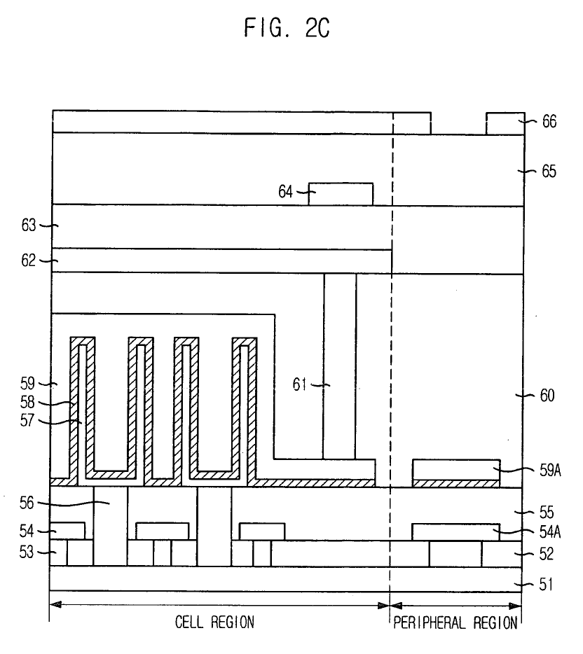

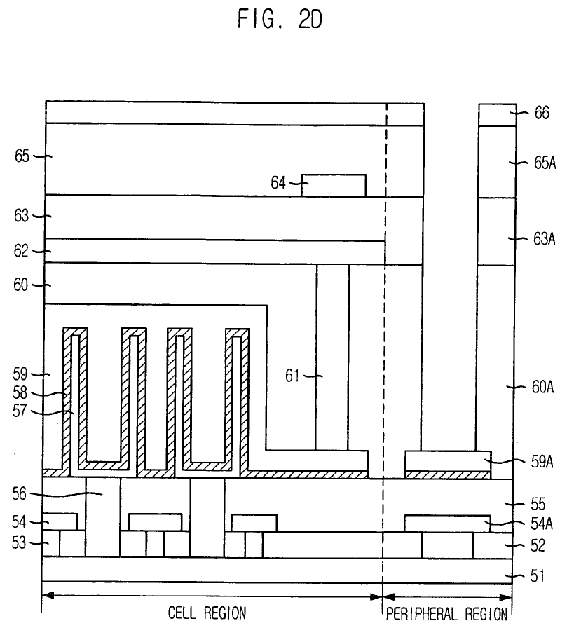

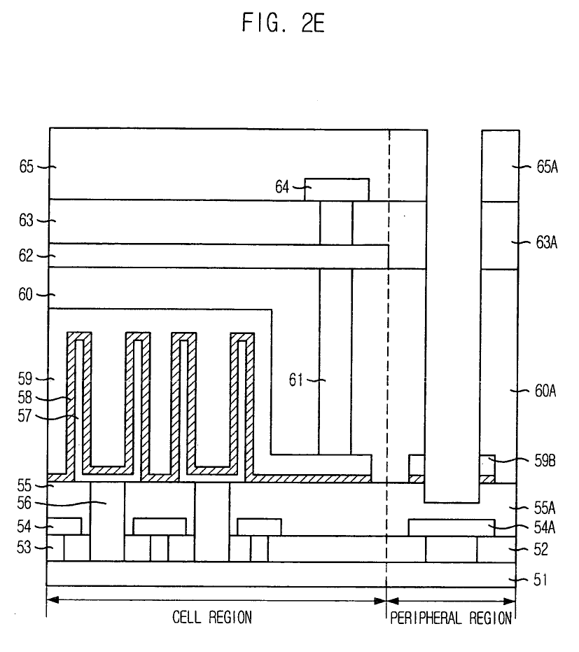

FIGS. 2A to 2E illustrate a method for fabricating a semiconductor device in accordance with an embodiment of the present invention. As shown in FIG. 2A, a first insulation layer 52 is formed over an upper portion of a substrate 51. The substrate 51 can include an isolation layer, a well and a gate line of a transistor. The first insulation layer 52 includes a silicon oxide layer for inter-layer insulation between a bottom conductive layer such as the gate line and a subsequent bit line.

A plurality of bit line contact plugs 53 connected to a lower layer penetrating the first insulation layer 52 are formed. The lower layer connected to the bit line contact plugs 53 can be a source or a drain of the transistor. The bit line contact plugs 53 include a conductive material such as polysilicon.

A conductive layer is formed. Then, the conductive layer is patterned to form a plurality of bit lines 54 connected to the bit line contact plugs 53 in a cell region and a fuse line 54A in a peripheral region.

A second insulation layer 55 is formed over the above resultant structure including the bit lines 54 and the fuse line 54A. The second insulation layer 55 includes a silicon oxide layer as an inter-layer insulation material.

A plurality of storage node contact plugs 56 penetrating the second insulation layer 55 of the cell region are formed. The storage node contact plugs 56 serve a role in connecting the lower layer to subsequent capacitors. The storage node contact plugs 56 include a conductive material such as polysilicon.

A plurality of bottom electrodes 57 connected to the storage node contact plugs 56 of the cell region are formed. A dielectric layer 58 and a top electrode 59 are formed over the bottom electrodes 57. A conductive layer forming the top electrode 59 is patterned over the second insulation layer 55 of the peripheral area to be overlapped with the fuse line 54A. As a result, a first patterned conductive layer 59A is obtained, and a line width of the first patterned conductive layer 59A is greater than that of the fuse line 54A. The first patterned conductive layer 59A serves a role of an etch stop during a repair etching process performed to form a subsequent fuse box. The first patterned conductive layer 59A can include a metal-based thin film.

A third insulation layer 60 is formed over the above resultant structure. The third insulation layer 60 includes a silicon oxide layer to serve a role of inter-layer insulation against a subsequent metal line.

As shown in FIG. 2B, a metal contact plug 61 penetrating the third insulation layer 60 of the cell region is formed. The metal contact plug 61 includes a conductive material such as polysilicon.

A first metal line 62 connected to the metal contact plug 61 is formed. A fourth insulation layer 63 is formed over the first metal line 62. The fourth insulation layer 63 includes an inter-metal dielectric layer to serve a role of inter-layer insulation between metal lines.

A second metal line 64 is formed over the fourth insulation layer 63. A passivation layer 65 is formed over an entire surface of the fourth insulation layer 63 including the second metal line 64.

As shown in FIG. 2C, a repair mask pattern 66 exposing a fuse box region is formed over the passivation layer 65. As shown in FIG. 2D, the passivation layer 65, the fourth insulation layer 63, and the third insulation layer 60 are etched using the repair mask pattern 66 as an etch mask. As a result, a patterned passivation layer 65A, a patterned fourth insulation layer 63A, and a patterned third insulation layer 60A are obtained. The etching process is set to be stopped at the first patterned conductive layer 59A of the peripheral region.

As shown in FIG. 2E, the first patterned conductive layer 59A is etched, and the dielectric layer 58 and the second insulation layer 55 beneath the first patterned conductive layer 59A are continuously etched. As a result, a second patterned conductive layer 59B and a patterned second insulation layer 55A are obtained. The patterned second insulation layer 55A remains over the fuse line 54A at a thickness ranging from about 2,000 Å to about 3,000 Å.

As described above, when the top electrode of the capacitor is formed in the cell region, the conductive layer forming the top electrode is also patterned over the fuse line of the peripheral region. During performing the repair etching process, the patterned conductive layer serves a role of the etch stop. Then, the patterned conductive layer, the dielectric layer beneath the patterned conductive layer, and the second insulation layer are etched to form a fuse box. Since a thickness of a layer subjected to a second repair etching process is smaller than that of a typical layer subjected to an etching process. Accordingly, a thickness of the insulation layer remaining over the fuse box can be uniformly formed.

According to this embodiment of the present invention, the insulation layer can be formed over an upper portion of the fuse line to a uniform thickness. As a result, those limitations associated with the process can be overcome in advance and accordingly, yield of devices can be improved.

While the present invention has been described with respect to the specific embodiments, it will be apparent to those skilled in the art that various changes and modifications may be made without departing from the spirit and scope of the invention as defined in the following claims.

What is claimed is:

1. A method for fabricating a semiconductor device, comprising:
forming a fuse line over a first region of a substrate;
forming a first insulation layer over the fuse line and the substrate;
forming a capacitor including an electrode over a second region of the substrate, such that a conductive layer for the electrode is patterned over the first insulation layer of the first region to overlap with the fuse line;
forming a second insulation layer over the capacitor;
etching the second insulation layer using the patterned conductive layer of the first region as an etch stop layer; and
etching the patterned conductive layer and the first insulation layer to make a portion of the first insulation layer remain over the fuse line at a certain thickness.

2. The method of claim 1, wherein the conductive layer includes a metal-based thin film.

3. The method of claim 1, wherein the second insulation layer includes a silicon oxide layer.

4. The method of claim 1, wherein the certain thickness of the first insulation layer over the fuse line ranges from about 2,000 Å to 3,000 Å.

5. The method of claim 1, wherein the electrode is a top electrode of the capacitor.

6. A method for fabricating a semiconductor device including a cell region and a peripheral region, the method comprising:
forming a first conductive layer over a substrate;
patterning the first conductive layer to form a bit line in the cell region and a fuse line in the peripheral region;
forming a first insulation layer over the resultant structure obtained by forming the bit line in the cell region and the fuse line in the peripheral region;
forming a capacitor including a bottom electrode, a dielectric layer, and a top electrode in the cell region, such that a conductive layer for the top electrode is patterned over the first insulation layer of the peripheral region to be overlapped with the fuse line;
forming a second insulation layer over the capacitor;
etching the second insulation layer using the patterned conductive layer of the peripheral region as an etch stop layer; and
etching the patterned conductive layer and the first insulation layer to make a portion of the first insulation layer remain over the fuse line at a certain thickness.

7. The method of claim 6, wherein the conductive layer includes a metal-based thin film.

8. The method of claim 6, wherein the second insulation layer is formed in a stack structure of multiple insulation layers including a passivation layer.

9. The method of claim 6, wherein the certain thickness of the first insulation layer over the fuse line ranges from about 2,000 Å to 3,000 Å.

10. The method of claim 6, wherein the patterned conductive layer over the first insulation layer of the peripheral region has a line width greater than the fuse line.
